(19) United States
(12) Patent Application Publication
(10) Pub. No.: US 2026/0143671 A1
(43) Pub. Date: May 21, 2026

(54) SEMICONDUCTOR DEVICE

(71) Applicant: Samsung Electronics Co., Ltd., Suwon-si (KR)

(72) Inventors: Sungnam Lyu, Suwon-si (KR); Sukhoon Kim, Suwon-si (KR); Hyojung Noh, Suwon-si (KR); Dosun Lee, Suwon-si (KR); Jaehun Han, Suwon-si (KR)

(21) Appl. No.: 19/336,752

(22) Filed: Sep. 23, 2025

(30) Foreign Application Priority Data
Nov. 18, 2024 (KR) 10-2024-0164011

(51) Int. Cl. H10B 12/00

(52) U.S. Cl. CPC H10B 12/30

(57) ABSTRACT

A semiconductor device including a substrate, a plurality of semiconductor patterns on the substrate, a bit line contacting a first end portion of each semiconductor pattern in a first direction and extending in a third direction perpendicular to an upper surface of the substrate, a plurality of word lines overlapping the plurality of semiconductor patterns, respectively, in the third direction and extending in a second direction intersecting the first direction, and a plurality of capacitors contacting a second end portion of each semiconductor pattern along the first direction. Each word line includes a first conductive liner layer, a second conductive liner layer, and a conductive layer sequentially positioned on each semiconductor pattern. The first conductive liner layer and the second conductive liner layer include different materials from each other or include same materials having different composition ratios from each other.

### CROSS-REFERENCE TO RELATED APPLICATION

This application claims priority to and the benefit of Korean Patent Application No. 10-2024-0164011, filed in the Korean Intellectual Property Office on Nov. 18, 2024, the entire contents of which are incorporated herein by reference.

### BACKGROUND

An integration density of semiconductor devices is desired to be increased. In the case of a two-dimensional semiconductor device, an integration level is mainly determined by an area occupied by a unit memory cell, and this aspect of integration level may be affected by a level of fine pattern formation technology.

However, the fine pattern formation technology uses expensive equipment and still limits the integration of two-dimensional semiconductor device. Three-dimensional semiconductor memory devices including three-dimensionally arranged memory cells have been proposed.

### SUMMARY

Implementations attempt to provide a semiconductor device capable of controlling a threshold voltage of a word line and improving defects caused by bending.

Some implementations of the present disclosure provides a semiconductor device including a substrate, a plurality of semiconductor patterns on the substrate, a bit line contacting a first end portion of each of the plurality of semiconductor patterns in a first direction and extending in a third direction perpendicular to an upper surface of the substrate; a plurality of word lines overlapping the plurality of semiconductor patterns, respectively, in the third direction and extending in a second direction intersecting the first direction, and a plurality of capacitors contacting a second end portion of each of the plurality of semiconductor patterns along the first direction, wherein each of the plurality of word lines comprises a first conductive liner layer, a second conductive liner layer, and a conductive layer sequentially positioned on each of the plurality of semiconductor patterns, wherein the first conductive liner layer and the second conductive liner layer include different materials from each other, or include same materials having different composition ratios from each other.

Some implementations of the present disclosure provides a semiconductor device including a substrate, a plurality of semiconductor patterns on the substrate, a bit line contacting a first end portion of each of the plurality of semiconductor patterns in a first direction and extending in a third direction perpendicular to an upper surface of the substrate, a plurality of word lines overlapping the plurality of semiconductor patterns, respectively, in the third direction and extending in a second direction intersecting the first direction, and a plurality of capacitors contacting a second end portion of each of the plurality of semiconductor patterns along the first direction, wherein each of the plurality of word lines comprises a first conductive liner layer positioned on each of the plurality of semiconductor patterns, a second conductive liner layer positioned on the first conductive liner layer, and a conductive layer positioned on the second conductive liner layer, wherein the conductive layer is thicker than each of the first conductive liner layer and the second conductive liner layer.

Some implementations of the present disclosure provides a semiconductor device including a substrate; a plurality of semiconductor patterns and a plurality of interlayer insulating layers alternately on the substrate, a bit line contacting a first end portion of each of the plurality of semiconductor patterns in a first direction and extending in a third direction perpendicular to an upper surface of the substrate, a plurality of word lines overlapping the plurality of semiconductor patterns, respectively, in the third direction and extending in a second direction intersecting the first direction, and a plurality of capacitors contacting a second end portion of each of the plurality of semiconductor patterns along the first direction, wherein each of the plurality of word lines comprises a first conductive liner layer, a second conductive liner layer, and a conductive layer, wherein each of the plurality of word lines is positioned in an order of the first conductive liner layer, the second conductive liner layer, the conductive layer, the second conductive liner layer, and the first conductive liner layer between a semiconductor pattern and an interlayer insulating layer adjacent to each other among the plurality of semiconductor patterns and the plurality of interlayer insulating layers, and wherein the first conductive liner layer and the second conductive liner layer include different materials from each other or include same materials having different composition ratios from each other.

According to some implementations, electrical characteristics of a semiconductor device may be improved and defects caused by bending may be improved.

### BRIEF DESCRIPTION OF THE DRAWINGS

FIG. 1 illustrates a cross-sectional view of a semiconductor device according to some implementations.

FIG. 2 illustrates a cross-sectional view of a semiconductor device according to some implementations taken along line A-A′ of FIG. 1.

FIG. 3 illustrates a cross-sectional view of a semiconductor device according to some implementations taken along line A-A′ of FIG. 1.

FIG. 4 illustrates a cross-sectional view of a semiconductor device according to some implementations taken along line A-A′ of FIG. 1.

### DETAILED DESCRIPTION

The present disclosure will be described more fully hereinafter with reference to the accompanying drawings, in which implementations of the disclosure are shown. As those skilled in the art would realize, the described implementations may be modified in various different ways, all without departing from the spirit or scope of the present disclosure.

To clearly describe the present disclosure, parts that are irrelevant to the description are omitted, and like numerals refer to like or similar components throughout the specification.

Further, since sizes and thicknesses of constituent members shown in the accompanying drawings are arbitrarily given for better understanding and ease of description, the present disclosure is not limited to the illustrated sizes and thicknesses. In the drawings, the thicknesses of layers, films, panels, regions, etc., are exaggerated for clarity. In the drawings, for better understanding and ease of description, the thicknesses of some layers and areas are exaggerated.

It will be understood that when an element such as a layer, film, region, or substrate is referred to as being “on” another element, it can be directly on the other element or intervening elements may also be present. In contrast, when an element is referred to as being “directly on” another element, there are no intervening elements present. Further, in the specification, the word “on” or “above” means positioned on or below the object portion, and does not necessarily mean positioned on the upper side of the object portion based on a gravitational direction.

In addition, unless explicitly described to the contrary, the word “comprise” and variations such as “comprises” or “comprising” will be understood to imply the inclusion of stated elements but not the exclusion of any other elements.

Further, throughout the specification, the phrase “in a plan view” means when an object portion is viewed from above, and the phrase “in a cross-sectional view” means when a cross-section taken by vertically cutting an object portion is viewed from the side.

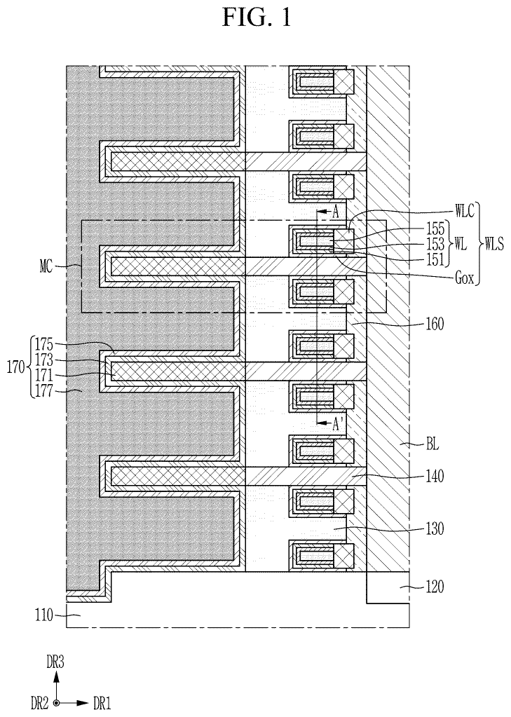

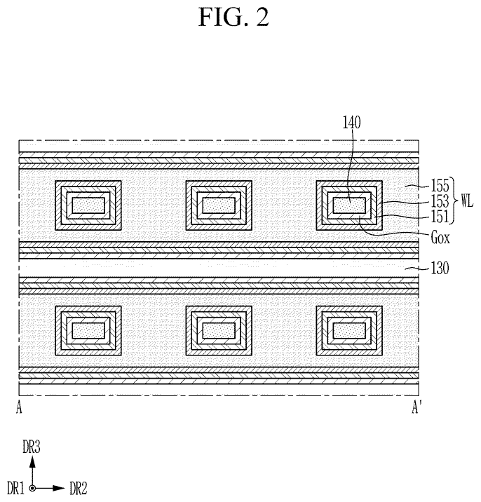

Hereinafter, a semiconductor device according to some implementations will be described with reference to FIG. 1 and FIG. 2.

FIG. 1 illustrates a cross-sectional view of a semiconductor device according to some implementations. FIG. 2 illustrates a cross-sectional view of a semiconductor device according to some implementations taken along line A-A′ of FIG. 1.

Referring to FIGS. 1 and 2, the semiconductor device according to some implementations may include a substrate 110, a plurality of semiconductor patterns 140 stacked on the substrate 110, a bit line BL that contacts a first end of each of the semiconductor patterns 140 along a first direction DR1 and extends in a third direction DR3 perpendicular to an upper surface of the substrate 110, a plurality of word lines WL that overlap each of the semiconductor patterns 140 in the third direction DR3 and extend in a second direction DR2 intersecting the first direction DR1, and a plurality of capacitors 170 that contact a second end of each of the semiconductor patterns 140 along the first direction DR1. The first direction DR1 and the second direction DR2 may be directions parallel to an upper surface of the substrate 110. The second direction DR2 may be, e.g., a direction orthogonal to the first direction DR1.

The substrate 110 may include a semiconductor material. For example, the substrate 110 may include a group IV semiconductor, a group III-V compound semiconductor, a group II-VI compound semiconductor, and the like. For example, the substrate 100 may include a semiconductor such as Si or Ge, or a compound semiconductor such as SiGe, SiC, GaAs, InAs, or InP. For example, the substrate 110 may be a monocrystalline epitaxial layer grown on a monocrystalline silicon substrate. However, a material included in the substrate 100 is not limited thereto, and may be variously changed.

A plurality of semiconductor patterns 140 and a plurality of interlayer insulating layers 130 may be alternately stacked on the substrate 110. An interlayer insulating layer 130, a semiconductor pattern 140, an interlayer insulating layer 130, and a semiconductor pattern 140 may be repeatedly stacked in this order on the substrate 110. A plurality of semiconductor patterns 140 and a plurality of interlayer insulating layers 130 may be arranged along the third direction DR3. In FIG. 1, four semiconductor patterns 140 and five interlayer insulating layers 130 are shown to be stacked, but the present disclosure is not limited thereto, and a greater number of semiconductor patterns 140 and a greater number of interlayer insulating layers 130 may be stacked in the third direction DR3.

The semiconductor patterns 140 may include a semiconductor material. For example, the semiconductor patterns 140 may include silicon, germanium, or silicon-germanium. For example, the semiconductor patterns 140 may include monocrystalline silicon or polycrystalline silicon.

The semiconductor patterns 140 may be extended in the first direction DR1. The semiconductor pattern 140 may include a first end and a second end along the first direction DR1. The first end of the semiconductor pattern 140 along the first direction DR1 may be in contact with the bit line BL. The second end of the semiconductor pattern 140 along the first direction DR1 may be in contact with the capacitor 170. The first end and the second end of the semiconductor pattern 140 along the first direction DR1 in contact with the bit line BL and the capacitor 170 may each include an impurity region. The semiconductor pattern 140 may include a channel region between the impurity regions.

The semiconductor patterns 140 may be arranged spaced apart in the second direction DR2. The semiconductor patterns 140 may be spaced apart and arranged in the first direction DR1. The bit line BL or the capacitor 170 may be positioned between the semiconductor patterns 140 spaced apart and arranged in the first direction DR1.

The interlayer insulating layer 130 may be positioned between the semiconductor patterns 140. The interlayer insulating layer 130 may be positioned between the semiconductor patterns 140 spaced apart in the third direction DR3.

The interlayer insulating layer 130 may include an insulating material. For example, the interlayer insulating layer 130 may include a silicon oxide, a silicon nitride, or a silicon oxynitride, but the present disclosure is not limited thereto.

The bit line BL extending in the third direction DR3 may be positioned on the substrate 110. The semiconductor patterns 140 stacked in the third direction DR3 may be connected to the same bit line BL. Although one bit line BL is illustrated in FIG. 1, the present disclosure is not limited thereto, and a semiconductor device according to some implementations may include a plurality of bit lines BL. The bit lines BL may be spaced and arranged along the first direction DR1 and the second direction DR2.

In some implementations, the bit line BL may have a column shape, but the present disclosure is not limited thereto. For example, the bit line BL may have a cylindrical shape. The bit line BL may include a conductive material. The conductive material may include, e.g., a doped semiconductor material, a conductive metal nitride, a metal, a metal-semiconductor compound, or a combination thereof. In some implementations, the bit line BL may include doped polysilicon. However, the present disclosure is not limited thereto, and the shape, material, etc. of the bit line BL may be changed in various ways.

A first insulating pattern 120 may be positioned between the substrate 110 and the bit line BL. The bit line BL may be separated and insulated from the substrate 110 by the first insulating pattern 120. The first insulating pattern 120 may have a form embedded in an upper surface of the substrate 110. An upper surface of the first insulating pattern 120 may be positioned at substantially a same level as the upper surface of the substrate 110, but the present disclosure is not limited thereto. In some cases, the upper surface of the first insulating pattern 120 may be positioned at a higher level than an upper surface of the substrate 110.

The first insulating pattern 120 may include an insulating material. For example, the first insulating pattern 120 may include at least one of a silicon oxide, a silicon nitride, and a silicon nitride, but the present disclosure is not limited thereto, and a material of the first insulating pattern 120 may vary. The first insulating pattern 120 may be formed as a single layer or multiple layers.

In some implementations, word lines WL may be positioned at opposite sides of the semiconductor pattern 140. The word lines WL may be positioned at opposite sides along the third direction DR3 of the semiconductor pattern 140. The word lines WL may overlap the semiconductor pattern 140 in the third direction DR3. In some implementations, the word lines WL may surround the semiconductor pattern 140. The word line WL may have a gate-all-around (GAA) structure surrounding a channel region of the semiconductor pattern 140. The word line WL may surround an outer surface of the semiconductor pattern 140 with the first direction DR1 as a central axis. In this case, the word line WL may not completely surround the outer surface of the semiconductor pattern 140 with the first direction DR1 as the central axis. For example, the word line WL may not surround opposite ends and adjacent portions of the outer surface of the semiconductor pattern 140 with the first direction DR1 as the central axis. The word line WL may surround a middle portion between both ends of an outer peripheral surface of the semiconductor pattern 140 with the first direction DR1 as the central axis. In some implementations, the semiconductor pattern 140 has a quadrangular pillar shape extending in the first direction DR1, and the word line WL may surround four sides of the semiconductor pattern 140. In some implementations, the word line WL may surround surfaces of the semiconductor pattern 140 facing in the third direction DR3 and surfaces facing in the second direction DR2.

In some implementations, the word line WL may extend in the second direction DR2. The word line WL may cover surfaces facing each other in the third direction DR3 of the semiconductor patterns 140 arranged in the second direction DR2. In some implementations, the word line WL may be positioned between the semiconductor patterns 140 arranged in the second direction DR2. The word line WL may be electrically connected to each of the semiconductor patterns 140 arranged in a second direction DR2.

A semiconductor device according to some implementations may include a plurality of word lines WL corresponding to the respective semiconductor patterns 140 arranged in the third direction DR3. The word lines WL may be arranged in the third direction DR3. Among the word lines WL, a lowermost word line WL adjacent to an upper surface of the substrate 110 and an uppermost word line WL positioned farthest from the upper surface of the substrate 110 may not be electrically connected to the semiconductor pattern 140. The interlayer insulating layer 130 may be positioned between the word lines WL arranged in the third direction DR3.

In some implementations, each of the word lines WL may include a first conductive liner layer 151, a second conductive liner layer 153, and a conductive layer 155. The first conductive liner layer 151, the second conductive liner layer 153, and the conductive layer 155 may be sequentially stacked on the semiconductor pattern 140. The first conductive liner layer 151 may be positioned on the semiconductor pattern 140, the second conductive liner layer 153 may be positioned on the first conductive liner layer 151, and the conductive layer 155 may be positioned on the second conductive liner layer 153. The first conductive liner layer 151 may be positioned outside the semiconductor pattern 140 to surround the semiconductor pattern 140. The second conductive liner layer 153 may be positioned outside the first conductive liner layer 151 to surround the first conductive liner layer 151. The conductive layer 155 may be positioned outside the second conductive liner layer 153 to surround the second conductive liner layer 153. The first conductive liner layer 151 positioned at an inner side of the conductive layer 155 and the first conductive liner layer 151 positioned at an outer side of the conductive layer 155 may be connected between the conductive layer 155 and the capacitor 170. The second conductive liner layer 153 positioned at an inner side of the conductive layer 155 and the second conductive liner layer 153 positioned at an outer side of the conductive layer 155 may be connected between the conductive layer 155 and the capacitor 170.

In some implementations, in a cross-section along the first direction DR1 and the third direction DR3 of FIG. 1, the first conductive liner layer 151, the second conductive liner layer 153, the conductive layer 155, the second conductive liner layer 153, and the first conductive liner layer 151 may be sequentially positioned between the semiconductor pattern 140 and the interlayer insulating layer 130 adjacent in the third direction DR3. In the cross-section along the first direction DR1 and the third direction DR3, the first conductive liner layer 151 may surround the second conductive liner layer 153, and the second conductive liner layer 153 may surround the conductive layer 155. In the cross-section along the first direction DR1 and the third direction DR3, the conductive layer 155 may be surrounded by the first conductive liner layer 151 and the second conductive liner layer 153. In the cross-section along the first direction DR1 and the third direction DR3, the conductive layer 155 may fill the space surrounded by the first conductive liner layer 151 and the second conductive liner layer 153.

In some implementations, the semiconductor pattern 140 may be positioned approximately at a center between the interlayer insulating layers 130 adjacent in the third direction DR3. A gate insulating layer Gox may surround the semiconductor pattern 140. The gate insulating layer Gox may further cover the semiconductor pattern 140 and the interlayer insulating layers 130 adjacent in the third direction DR3. Gate insulating layers Gox surrounding the semiconductor patterns 140 arranged in the second direction DR2 may be connected to each other in the second direction DR2. The first conductive liner layer 151 may surround the semiconductor pattern 140 and the gate insulating layer Gox surrounding the semiconductor pattern 140. The first conductive liner layer 151 may further cover the gate insulating layer Gox covering the interlayer insulating layers 130. First conductive liner layers 151 surrounding the semiconductor patterns 140 arranged in the second direction DR2 may be connected to each other in the second direction DR2. The second conductive liner layer 153 may surround the semiconductor pattern 140, the gate insulating layer Gox surrounding the semiconductor pattern 140, and the first conductive liner layer 151. The second conductive liner layer 153 may further cover the gate insulating layer Gox covering the interlayer insulating layers 130, and the first conductive liner layer 151. Second conductive liner layers 153 surrounding the semiconductor patterns 140 arranged in the second direction DR2 may be connected to each other in the second direction DR2. The conductive layer 155 may surround the semiconductor pattern 140, the gate insulating layer Gox surrounding the semiconductor pattern 140, the first conductive liner layer 151, and the second conductive liner layer 153. The conductive layer 155 may further cover the first conductive liner layer 151, the second conductive liner layer 153, and the gate insulating layer Gox covering the interlayer insulating layers 130. Conductive layers 155 surrounding the semiconductor patterns 140 arranged in the second direction DR2 may be connected to each other in the second direction DR2. In some implementations, the conductive layer 155 may be positioned between the semiconductor patterns 140 arranged in the second direction DR2.

In some implementations, the conductive layer 155 may be thicker than the first conductive liner layer 151 and the second conductive liner layer 153. Herein, a thickness of the conductive layer 155 may indicate a width (or length) along the third direction DR3 overlapping the semiconductor pattern 140, and thicknesses of the first conductive liner layer 151 and the second conductive liner layer 153 may indicate a width (or length) along the third direction DR3 between the semiconductor pattern 140 and the conductive layer 155. In some implementations, the thicknesses of the first conductive liner layer 151 and the second conductive liner layer 153 may each be greater than or equal to about 3 Å (Angstroms) and less than or equal to about 100 Å (Angstroms).

Each of the first conductive liner layer 151, the second conductive liner layer 153, and the conductive layer 155 may include a conductive material. In some implementations, the first conductive liner layer 151 and the second conductive liner layer 153 may include different materials or may include the same materials having different composition ratios. The first conductive liner layer 151 and the second conductive liner layer 153 may include different materials, or may include the same materials having different composition ratios, thereby playing different roles within the word line WL.

In some implementations, the first conductive liner layer 151 and the second conductive liner layer 153 may include different materials. For example, the first conductive liner layer 151 may include at least one of TiSiN, MoSiN, TaSiN, LaSiN, TiAlN, TiAlC, TiWN, TaN, and LaN, and the second conductive liner layer 153 may include at least one of MoN, TiN, W, Mo, Ta, Al, Cu, and Ru.

In some implementations, the first conductive liner layer 151 and the second conductive liner layer 153 may include the same materials having different composition ratios. For example, the first conductive liner layer 151 and the second conductive liner layer 153 may include at least one of TiSiN, MoSiN, TaSiN, LaSiN, TiAlN, TiAlC, and TiWN. A mass ratio of Si, Al, or W included in the first conductive liner layer 151 may be greater than 12%, and a mass ratio of Si, Al, or W included in the second conductive liner layer 153 may be less than 12%.

The first conductive liner layer 151 may play a role in controlling a work function of the word line WL. That is, the first conductive liner layer 151 may control a threshold voltage Vₜₕ and a flat-band voltage V_{fb} of the word line WL. Furthermore, the first conductive liner layer 151 may reduce a number (or density) of charges trapped at an interface between the semiconductor pattern 140 and the gate insulating pattern Gox.

The second conductive liner layer 153 may increase a grain size of the conductive layer 155 positioned on the second conductive liner layer 153. As the crystal grain size of the conductive layer 155 increases, resistance of the conductive layer 155 may be reduced. Furthermore, a phenomenon (agglomeration) of fine particles of the conductive layer 155 may be prevented. Accordingly, it may be possible to prevent a phenomenon of bending of the conductive layer 155 and prevent an occurrence of voids inside the conductive layer 155. Furthermore, the second conductive liner layer 153 may prevent impurities generated during deposition of the conductive layer 155 from penetrating into the semiconductor pattern 140 and causing defects.

In some implementations, each of the first conductive liner layer 151 and the second conductive liner layer 153 may include a different material from that of the conductive layer 155. For example, the conductive layer 155 may include at least one of TiN, W, Mo, Ta, Al, Cu, and Ru, but the present disclosure is not limited thereto. For example, when the conductive layer 155 includes TiN, each of the first conductive liner layer 151 and the second conductive liner layer 153 may include at least one of the materials excluding TiN among the material examples described above. The conductive layer 155 and the second conductive liner layer 153 that come into contact with each other but include different materials, so an oxide film may not be formed between the conductive layer 155 and the second conductive liner layer 153.

A word line capping pattern WLC may be positioned on a side surface of the word line WL. The word line capping pattern WLC may cover a side surface of the word line WL facing bit line BL on the semiconductor pattern 140. The semiconductor device according to some implementations may include a plurality of word line capping patterns WLC covering side surfaces of the respective word lines WL. The word line capping patterns WLC may be spaced apart in the third direction DR3 with the semiconductor pattern 140 therebetween. The word line capping patterns WLC may be spaced apart in the third direction DR3 with the interlayer insulating layer 130 therebetween.

The word line capping patterns WLC may include an insulating material. The word line capping patterns WLC may include a silicon nitride, but the present disclosure is not limited thereto. The word line capping patterns WLC may serve to protect the word line WL. The word line WL may be surrounded by the word line capping pattern WLC and the gate insulating pattern Gox described later.

The gate insulating pattern Gox may be positioned between the word line WL and the semiconductor pattern 140. The word line WL may be separated from the semiconductor pattern 140 by the gate insulating pattern Gox. The gate insulation pattern Gox may surround the word line WL. In FIG. 1, the gate insulating pattern Gox is illustrated as being further positioned between the word line capping pattern WLC and the semiconductor pattern 140, and between the word line capping pattern WLC and the interlayer insulating layer 130, but the present disclosure is not limited thereto. Structures and shapes of the word line capping pattern WLC and the gate insulating pattern Gox may be varied.

The gate insulating pattern Gox may include at least one of a high-k material, a silicon oxide, a silicon nitride, or a silicon oxynitride. The high dielectric constant material may include, e.g., at least one of a hafnium oxide, a hafnium silicon oxide, a lanthanum oxide, a zirconium oxide, a zirconium silicon oxide, a tantalum oxide, a titanium oxide, a barium strontium titanium oxide, a barium titanium oxide, a strontium titanium oxide, a lithium oxide, an aluminum oxide, a lead scandium tantalum oxide, or a lead zinc niobate.

The word line WL, the word line capping pattern WLC, and the gate insulating pattern Gox may form the word line structure WLS. The semiconductor device according to some implementations may include a plurality of word line structures WLS. The word line structures WLS may be arranged spaced apart in the third direction DR3. Each of the word line structures WLS arranged along the third direction DR3 may surround each of the semiconductor patterns 140 arranged in the third direction DR3. The interlayer insulating layer 130 may be positioned between the word line structures WLS arranged in the third direction DR3.

A second insulating pattern 160 may be positioned between the semiconductor patterns 140 arranged in the third direction DR3. The second insulating pattern 160 may cover a side surface of the interlayer insulating layer 130 between the semiconductor patterns 140. The second insulating pattern 160 may cover a side surface of the gate insulating pattern Gox and a side surface of the word line capping pattern WLC between the semiconductor patterns 140. The second insulating pattern 160 may further cover upper and lower surfaces of the word line capping pattern WLC between the semiconductor patterns 140, but the present disclosure is not limited thereto. For example, when the upper and lower surfaces of the word line capping pattern WLC are covered by the gate insulating pattern Gox, the second insulating pattern 160 may cover the side surface of the word line capping pattern WLC.

The second insulating pattern 160 may include an insulating material. For example, the second insulating pattern 160 may include at least one of a silicon oxide or a silicon nitride. In FIG. 1, the second insulating pattern 160 is illustrated as being a single layer, but the present disclosure is not limited thereto. According to some implementations, the second insulating pattern 160 may be formed of multiple layers. For example, the second insulating pattern 160 may have a structure in which a silicon oxide film, a silicon nitride film, and a silicon oxide film are alternately stacked on the side surface of the word line structure WLS and the side surface of the interlayer insulating layer 130.

As described above, a first end of the semiconductor pattern 140 along the first direction DR1 may be in contact with the bit line BL, and a second end of the semiconductor pattern 140 along the first direction DR1 may be in contact with the capacitor 170. The capacitor 170 may include a first electrode 171, a dielectric layer 173, a second electrode 175, and a plate electrode 177. The second end of the semiconductor pattern 140 along the first direction DR1 may be in contact with the first electrode 171 of the capacitor 170. The first electrode 171 may be arranged parallel to the semiconductor pattern 140 along the first direction DR1.

The semiconductor device according to some implementations may include a plurality of capacitors 170. The capacitors 170 each may include one first electrode 171. The semiconductor device according to some implementations may include a plurality of first electrodes 171. The first electrodes 171 may be stacked in the third direction DR3. A first end of each of the first electrodes 171 along the first direction DR1 may come into contact with a respective one of each of the semiconductor patterns 140 stacked in the third direction DR3.

The dielectric layer 173 may surround the first electrode 171. The dielectric layer 173 may conformally cover surfaces of the first electrode 171 except a surface in contact with the semiconductor pattern 140. The dielectric layer 173 may cover a plurality of first electrodes 171 that are stacked in the third direction DR3. The dielectric layer 173 may cover a side surface of the interlayer insulating layer 130 positioned between adjacent first electrodes 171 in third direction DR3. The dielectric layer 173 may cover an upper surface of the substrate 110.

The second electrode 175 may cover the dielectric layer 173. The second electrode 175 may be separated from the first electrode 171 by the dielectric layer 173. The second electrode 175 may conformally cover a surface of the dielectric layer 173. The second electrode 175 may have a similar shape to the dielectric layer 173.

The plate electrode 177 may cover the second electrode 175. The plate electrode 177 may include a vertical portion extending in the third direction DR3 and horizontal portions extending to opposite sides from the vertical portion in the first direction DR1. A lower portion of the vertical portion of the plate electrode 177 may be surrounded by the substrate 110. The vertical portion of the plate electrode 177 may extend in the third direction DR3 across the first electrodes 171 that are stacked in the third direction DR3. The horizontal portions of the plate electrode 177 may be positioned between the first electrodes 171 stacked in the third direction DR3, and between a lowermost first electrode 171 among the first electrodes 171 and the substrate 110.

In some implementations, the dielectric layer 173 of each of the capacitors 170 may be formed integrally. For example, the first electrodes 171 stacked in third direction DR3 may be covered by a single dielectric layer 173. In some implementations, the second electrode 175 of each of the capacitors 170 may be formed integrally. For example, the first electrodes 171 stacked in third direction DR3 may be covered by a single second electrode 175. In some implementations, the plate electrode 177 of each of the capacitors 170 may be formed integrally. For example, the first electrodes 171 stacked in third direction DR3 may be covered by a single plate electrode 177.

The semiconductor device according to some implementations may further include a plurality of first electrodes 171 spaced apart from the first electrodes 171 illustrated in FIG. 1 in the first direction DR1 and stacked in the third direction DR3. The first electrodes 171 spaced apart in the first direction DR1 may be covered by a single dielectric layer 173, a single second electrode 175, and a single plate electrode 177. The capacitors 170 including the same dielectric layer 173, the same second electrode 175, and the same plate electrode 177 may have a mirror-symmetrical structure with respect to the plate electrode 177.

The semiconductor device according to some implementations may include a plurality of first electrodes 171 spaced apart and arranged in the second direction DR2 on a same layer. The first electrodes 171 positioned spaced apart in the second direction DR2 may be covered by a single dielectric layer 173, a single second electrode 175, and a single plate electrode 177. The dielectric layer 173 and the second electrode 175 may cover surfaces of the first electrode 171 facing the second direction DR2. The plate electrode 177 may extend in the second direction DR2. In some implementations, the dielectric layer 173 and the second electrode 175 may be positioned between the first electrodes 171 spaced apart in the second direction DR2, and the plate electrode 177 may not be positioned between the first electrodes 171 spaced apart in the second direction DR2. The first electrodes 171 may be arranged and spaced apart in the second direction DR2, and the plate electrode 177 may extend in the second direction DR2 from a side of the first electrodes 171 that is along the first direction DR1.

Each of the first electrode 171, the second electrode 175, and the plate electrode 177 may include a conductive material. Each of the first electrode 171, the second electrode 175, and the plate electrode 177 may include at least one of a metal material, a conductive metal nitride, or a doped semiconductor material. In some implementations, the first electrode 171 and the second electrode 175 may include a same material, and the plate electrode 177 may include a different material from that of the first electrode 171 and the second electrode 175. For example, the first electrode 171 and the second electrode 175 may include a titanium nitride, and the plate electrode 177 may include a doped silicon germanium.

The dielectric layer 173 may include at least one of a dielectric, a ferromagnetic material, or a semi-ferromagnetic material. The dielectric may include a high-k material. For example, the dielectric may include a hafnium oxide, a hafnium silicon oxide, a lanthanum oxide, a zirconium oxide, a zirconium silicon oxide, a tantalum oxide, a titanium oxide, a barium strontium titanium oxide, a barium titanium oxide, a strontium titanium oxide, a lithium oxide, an aluminum oxide, a lead scandium tantalum oxide, a lead zinc niobate, or a combination thereof.

The semiconductor device according to some implementations may include a plurality of memory cells MC stacked in the third direction DR3 perpendicular to an upper surface of the substrate 110. In some implementations, each of the memory cells MC may include at least one transistor and at least one capacitor. In some implementations, each of the memory cells MC may include a semiconductor pattern 140, a word line WL surrounding the semiconductor pattern 140 and electrically connected to the semiconductor pattern 140, a bit line BL connected to a first end of the semiconductor pattern 140, and a capacitor 170 connected to a second end of the semiconductor pattern 140.

The semiconductor device according to some implementations may include a first conductive liner layer 151 and a second conductive liner layer 153 between the gate insulating pattern Gox and a conductive layer 155, and the first conductive liner layer 151 and the second conductive liner layer 153 may include different materials or may include a same material but have different composition ratios. According to some implementations, a threshold voltage of the word line WL may be controlled by the first conductive liner layer 151, a number (or density) of charges trapped at an interface between the semiconductor pattern 140 and the gate insulating pattern Gox may be reduced, and a grain size of the conductive layer 155 may be increased by the second conductive liner layer 153. Accordingly, an electric characteristic of the semiconductor device may be improved, and defects caused by bending may be improved.

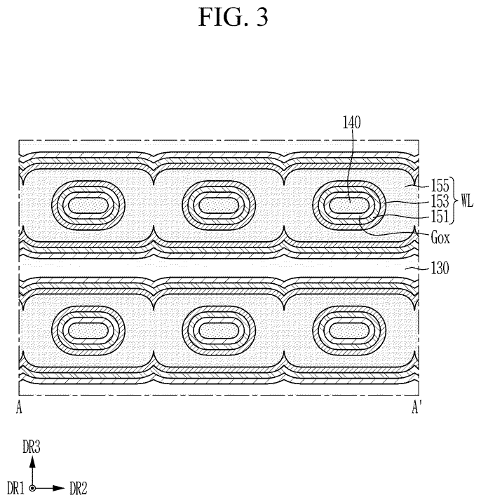

Hereinafter, a modified example of the semiconductor device illustrated in FIGS. 1 and 2 will be described with reference to FIG. 3.

FIG. 3 illustrates a cross-sectional view of a semiconductor device according to some implementations taken along line A-A′ of FIG. 1. The implementations illustrated in FIG. 3 may be substantially identical to the implementations illustrated in FIGS. 1 and 2. In some implementations illustrated in FIG. 3, the same components as in the implementations illustrated in FIGS. 1 and 2 may be referenced by the same symbols. Hereinafter, the comparative implementations illustrated in FIG. 3 will be described with a focus on differences from the implementations illustrated in FIGS. 1 and 2. The implementations illustrated in FIG. 3 may differ in some aspects from the implementations illustrated in FIGS. 1 and 2 in the shape of the semiconductor pattern 140 and the shapes of the gate insulating pattern Gox and the word line WL.

Referring to FIG. 3, the semiconductor pattern 140 according to some implementations may have a rounded corner shape in a cross-section along the second direction DR2 and the third direction DR3. In some implementations illustrated in FIG. 2, the cross-sectional shape of the semiconductor pattern 140 along the second direction DR2 and the third direction DR3 is a rectangle, whereas in some implementations illustrated in FIG. 3, the cross-sectional shape of the semiconductor pattern 140 along the second direction DR2 and the third direction DR3 may be a quadrangle with rounded corners. In some implementations, surfaces of the semiconductor pattern 140 facing the second direction DR2 may be curved. The surfaces facing the second direction DR2 of the semiconductor pattern 140 may be convex surfaces toward an outside of the semiconductor pattern 140. The gate insulating pattern Gox, the first conductive liner layer 151, the second conductive liner layer 153, and the conductive layer 155 surrounding the semiconductor pattern 140 may include a curved surface along a surface profile of the semiconductor pattern 140.

In some implementations, a thickness of the word line WL along the third direction DR3 may not be constant in the cross-section along the second direction DR2 and the third direction DR3. The thickness of the word line WL along the third direction DR3 may become thinner as it gets further away from side surfaces of the semiconductor patterns 140 arranged between the semiconductor patterns 140 in the second direction DR2. For example, between a first semiconductor pattern and a second semiconductor pattern that are adjacent in the second direction DR2, the thickness of the word line WL along the third direction DR3 on a side surface of the first semiconductor pattern may become thinner as it goes toward a middle position between the first semiconductor pattern and the second semiconductor pattern. The thickness of the word line WL along the third direction DR3 may become thicker as it goes toward the side surface of the second semiconductor pattern at the middle position between the first semiconductor pattern and the second semiconductor pattern.

In some implementations, the thickness of the conductive layer 155 along the third direction DR3 in the cross-section along the second direction DR2 and the third direction DR3 may become thinner from side surfaces of the semiconductor patterns 140 to the middle position of the semiconductor patterns 140 among the semiconductor patterns 140 arranged in the second direction DR2.

In some implementations, in the cross-section along the second direction DR2 and the third direction DR3, portions of the gate insulating layer Gox, portions of the first conductive liner layer 151, and portions of the second conductive liner layer 153 covering the interlayer insulating layers 130 positioned on both sides along the third direction DR3 in an extension of a middle position between adjacent semiconductor patterns 140 in the second direction DR2 may protrude toward each other in the third direction DR3. For example, the gate insulating layer Gox, the first conductive liner layer 151, and the second conductive liner layer 153 may cover a first interlayer insulating layer and a second interlayer insulating layer that are adjacent in the third direction DR3. In an extension of a middle position between adjacent semiconductor patterns 140 in the second direction DR2, a portion of the gate insulating layer Gox, a portion of the first conductive liner layer 151, and a portion of the second conductive liner layer 153 covering the first interlayer insulating layer may protrude in the third direction DR3 toward a portion of the gate insulating layer Gox, a portion of the first conductive liner layer 151, and a portion of the second conductive liner layer 153 covering the second interlayer insulating layer. In an extension of a middle position between adjacent semiconductor patterns 140 in the second direction DR2, a portion of the gate insulating layer Gox, a portion of the first conductive liner layer 151, and a portion of the second conductive liner layer 153 covering the second interlayer insulating layer may protrude in the third direction DR3 toward a portion of the gate insulating layer Gox, a portion of the first conductive liner layer 151, and a portion of the second conductive liner layer 153 covering the first interlayer insulating layer.

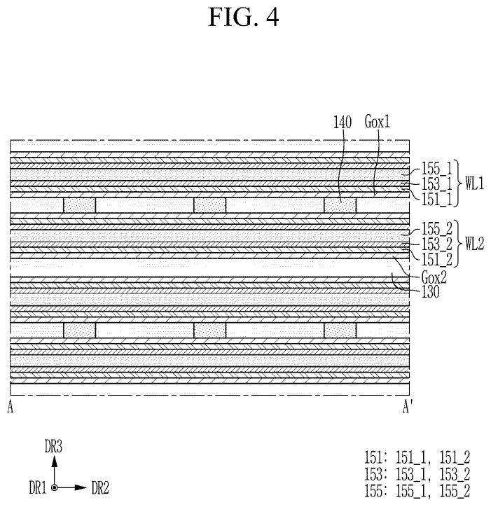

Hereinafter, a modified example of the semiconductor device illustrated in FIGS. 1 and 2 will be described with reference to FIG. 4.

FIG. 4 illustrates a cross-sectional view of a semiconductor device according to some implementations taken along line A-A′ of FIG. 1. The implementations illustrated in FIG. 4 may be substantially identical to the implementations illustrated in FIGS. 1 and 2. In the implementations illustrated in FIG. 4, the same components as in the implementations illustrated in FIGS. 1 and 2 may be referenced by the same symbols. Hereinafter, the comparative implementations illustrated in FIG. 4 will be described with a focus on differences from the implementations illustrated in FIGS. 1 and 2. The implementations illustrated in FIG. 4 may differ in some aspects from the implementations illustrated in FIGS. 1 and 2 in the shapes and the structures of the gate insulating pattern Gox and the word line WL.

Referring to FIG. 4, the word line WL according to some implementations may include a first word line WL1 and a second word line WL2 positioned at opposite sides of the semiconductor pattern 140 along the third direction DR3. The first word line WL1 and the second word line WL2 may be respectively positioned on surfaces of the semiconductor pattern 140 facing each other in the third direction DR3. The first word line WL1 and the second word line WL2 may be positioned at opposite sides of the semiconductor patterns 140 arranged in the second direction DR2. The first word line WL1 and the second word line WL2 may positioned at opposite sides of the semiconductor patterns 140 arranged in the second direction DR2, along the third direction DR3. The first word line WL1 and the second word line WL2 may not be positioned between the semiconductor patterns 140 arranged in the second direction DR2. The first word line WL1 and the second word line WL2 may be positioned with the semiconductor patterns 140 arranged in the second direction DR2 therebetween. The interlayer insulating layer 130 may be positioned between the semiconductor patterns 140 arranged in the second direction DR2. The first word line WL1 and the second word line WL2 may overlap the semiconductor pattern 140 in the third direction DR3, but may not overlap the second direction DR2.

In some implementations, the first word line WL1 and the second word line WL2 may respectively include first conductive liner layers 151_1 and 151_2, second conductive liner layers 153_1 and 153_2, and conductive layers 155_1 and 155_2. A first gate insulating pattern Gox1 may be positioned between the first word line WL1 and the semiconductor pattern 140, and between the first word line WL1 and the interlayer insulating layer 130. A second gate insulating pattern Gox2 may be positioned between the second word line WL2 and the semiconductor pattern 140, and between the second word line WL2 and the interlayer insulating layer 130. The first word line WL1 may be separated from the semiconductor pattern 140 by the first gate insulating pattern Gox1. The second word line WL2 may be separated from the semiconductor pattern 140 by the second gate insulating pattern Gox2.

In some implementations, the first gate insulating pattern Gox1 may extend in the second direction DR2 and cover facing surfaces of the semiconductor pattern 140 and the interlayer insulating layer 130 that are spaced apart from each other in the third direction DR3. The first conductive liner layer 151_1 of the first word line WL1 may cover the first gate insulating pattern Gox1 and may extend in the second direction DR2. The second conductive liner layer 153_1 of the first word line WL1 may cover the first conductive liner layer 151_1 and may extend in the second direction DR2. The conductive layer 155_1 of the first word line WL1 may cover the second conductive liner layer 153_1 and may extend in the second direction DR2.

In some implementations, the second gate insulating pattern Gox2 may extend in the second direction DR2 and cover facing surfaces of the semiconductor pattern 140 and the interlayer insulating layer 130 that are spaced apart from each other in the third direction DR3. The second conductive liner layer 151_2 of the second word line WL2 may cover the first gate insulating pattern Gox2 and may extend in the second direction DR2. The second conductive liner layer 153_2 of the second word line WL2 may cover the first conductive liner layer 151_2 of the second word line WL2 and may extend in the second direction DR2. The conductive layer 155_2 of the second word line WL2 may cover the second conductive liner layer 153_2 of the second word line WL2 and may extend in the second direction DR2.

In some implementations, the semiconductor pattern 140 may be electrically connected to two word lines WL. The semiconductor pattern 140 may be electrically connected to the first word line WL1 and the second word line WL2. According to some implementations, an area of a channel region of the semiconductor pattern 140 may be increased compared to a comparative example including one of the first word line WL1 and the second word line WL2, thereby improving an electrical characteristic of the semiconductor device. In some implementations, a same voltage may be applied to the first word line WL1 and the second word line WL2, but the present disclosure is not limited thereto. According to some implementations, different voltages may be applied to the first word line WL1 and the second word line WL2. In this case, a first one of the first word line WL1 and the second word line WL2 may be used as a front gate and a second one may be used as a back gate to improve the electrical characteristic of the semiconductor device.

While this specification contains many specific implementation details, these should not be construed as limitations on the scope of any invention or on the scope of what may be claimed, but rather as descriptions of features that may be specific to particular implementations of particular inventions. Certain features that are described in this specification in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

While this disclosure has been described in connection with what is presently considered to be practical implementations, it is to be understood that the disclosure is not limited to the disclosed implementations, but, on the contrary, is intended to cover various modifications and equivalent dispositions included within the spirit and scope of the appended claims.

What is claimed is:

1. A semiconductor device comprising:
a substrate;
a plurality of semiconductor patterns on the substrate;
a bit line contacting a first end portion of each of the plurality of semiconductor patterns in a first direction and extending in a third direction perpendicular to an upper surface of the substrate;
a plurality of word lines overlapping the plurality of semiconductor patterns, respectively, in the third direction and extending in a second direction intersecting the first direction; and
a plurality of capacitors contacting a second end portion of each of the plurality of semiconductor patterns along the first direction,
wherein each of the plurality of word lines comprises a first conductive liner layer, a second conductive liner layer, and a conductive layer sequentially positioned on each of the plurality of semiconductor patterns
wherein the first conductive liner layer and the second conductive liner layer include different materials from each other, or include same materials having different composition ratios from each other.

2. The semiconductor device of claim 1, wherein
the first conductive liner layer and the second conductive liner layer comprise different materials,
the first conductive liner layer comprises at least one of TiSiN, MoSiN, TaSiN, LaSiN, TiAlN, TiAlC, TiWN, TaN, or LaN, and
the second conductive liner layer comprises at least one of MoN, TiN, W, Mo, Ta, Al, Cu, or Ru.

3. The semiconductor device of claim 1, wherein
the first conductive liner layer and the second conductive liner layer include a same material,
the first conductive liner layer and the second conductive liner layer comprise at least one of TiSiN, MoSiN, TaSiN, LaSiN, TiAlN, TiAlC, or TiWN,
a mass ratio of Si, Al, or W of the first conductive liner layer exceeds 12%, and
a mass ratio of Si, Al, or W of the second conductive liner layer is less than 12%.

4. The semiconductor device of claim 1, wherein
each of the first conductive liner layer and the second conductive liner layer comprises a different material from a material of the conductive layer.

5. The semiconductor device of claim 1, wherein
the second conductive liner layer surrounds the conductive layer, and the first conductive liner layer surrounds the second conductive liner layer.

6. The semiconductor device of claim 1, wherein
the conductive layer is thicker than each of the first conductive liner layer and the second conductive liner layer.

7. The semiconductor device of claim 6, wherein
each of the first conductive liner layer and the second conductive liner layer has a thickness of 3 Å or more and 100 Å or less.

8. The semiconductor device of claim 1, wherein
each of the plurality of word lines surrounds first surfaces of each of the plurality of semiconductor patterns facing in the second direction and surrounds second surfaces of each of the plurality of semiconductor patterns facing in the third direction.

9. The semiconductor device of claim 8, wherein
the plurality of semiconductor patterns includes semiconductor patterns arranged in the second direction, and
each of the plurality of word lines is positioned between adjacent semiconductor patterns arranged in the second direction.

10. The semiconductor device of claim 9, wherein
in a cross-section along the second direction and the third direction, each of the plurality of semiconductor patterns has a rounded corner, and each of the plurality of word lines along the third direction becomes thinner as it is farther away from side surfaces of the semiconductor patterns that are arranged in the second direction,.

11. The semiconductor device of claim 1, wherein
each of the plurality of word lines include a first word line and a second word line, the first word line and the second word line being positioned on surfaces of each of the plurality of semiconductor patterns that face each other in the third direction, and
each of the first word line and the second word line comprises the first conductive liner layer, the second conductive liner layer, and the conductive layer.

12. The semiconductor device of claim 11, wherein
the first word line and the second word line are positioned at opposite sides of the semiconductor patterns that are arranged in the second direction.

13. A semiconductor device comprising:
a substrate;
a plurality of semiconductor patterns on the substrate;
a bit line contacting a first end portion of each of the plurality of semiconductor patterns in a first direction and extending in a third direction perpendicular to an upper surface of the substrate;
a plurality of word lines overlapping the plurality of semiconductor patterns, respectively, in the third direction and extending in a second direction intersecting the first direction; and
a plurality of capacitors contacting a second end portion of each of the plurality of semiconductor patterns along the first direction,
wherein each of the plurality of word lines comprises:
a first conductive liner layer positioned on each of the plurality of semiconductor patterns;
a second conductive liner layer positioned on the first conductive liner layer; and
a conductive layer positioned on the second conductive liner layer,
wherein the conductive layer is thicker than each of the first conductive liner layer and the second conductive liner layer.

14. The semiconductor device of claim 13, wherein
the second conductive liner layer comprises a different material from the first conductive liner layer.

15. The semiconductor device of claim 13, wherein
the first conductive liner layer and the second conductive liner layer comprise a same material having different composition ratios.

16. The semiconductor device of claim 13, wherein
the conductive layer comprises a different material from a material of the first conductive liner layer and the second conductive liner layer.

17. The semiconductor device of claim 13, wherein
each of the plurality of word lines surrounds an outer peripheral surface of the each of the plurality of semiconductor patterns with the first direction as a central axis.

18. The semiconductor device of claim 13, wherein
each of the plurality of the word lines comprises a first word line and a second word line positioned at opposite sides of each of the plurality of semiconductor patterns along the third direction.

19. A semiconductor device comprising:
a substrate;
a plurality of semiconductor patterns and a plurality of interlayer insulating layers alternately on the substrate;
a bit line contacting a first end portion of each of the plurality of semiconductor patterns in a first direction and extending in a third direction perpendicular to an upper surface of the substrate;
a plurality of word lines overlapping the plurality of semiconductor patterns, respectively, in the third direction and extending in a second direction intersecting the first direction; and
a plurality of capacitors contacting a second end portion of each of the plurality of semiconductor patterns along the first direction,
wherein each of the plurality of word lines comprises a first conductive liner layer, a second conductive liner layer, and a conductive layer,
wherein each of the plurality of word lines is positioned in an order of the first conductive liner layer, the second conductive liner layer, the conductive layer, the second conductive liner layer, and the first conductive liner layer between a semiconductor pattern and an interlayer insulating layer adjacent to each other among the plurality of semiconductor patterns and the plurality of interlayer insulating layers, and
wherein the first conductive liner layer and the second conductive liner layer include different materials from each other or include same materials having different composition ratios from each other.

20. The semiconductor device of claim 19, wherein
the first conductive liner layer and the second conductive liner layer comprise different materials from a material of the conductive layer.
